(19) United States
(12) Patent Application Publication
(10) Pub. No.: US 2010/0201658 A1
(43) Pub. Date: Aug. 12, 2010

(54) METHOD OF MANUFACTURING DISPLAY DEVICE AND DISPLAY DEVICE

(75) Inventors: Ryo Koshiishi, Kanagawa (JP); Manabu Kodate, Kanagawa (JP)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(73) Assignee: SONY CORPORATION, Tokyo (JP)

(21) Appl. No.: 12/699,413

(22) Filed: Feb. 3, 2010

(30) Foreign Application Priority Data
Feb. 10, 2009 (JP) 2009-028330

(51) Int. Cl. G06F 3/038; H01L 21/30

(52) U.S. Cl. 345/205; 438/4; 257/E21.211

(57) ABSTRACT

A method of manufacturing a display device is provided, in which interlayer short formed in a capacitor in a wiring board or in an intersection between wiring lines may be repaired, and a display device is provided. A method of manufacturing a display device comprising steps of: forming a wiring board having a lower conductive film, an insulating film and an upper conductive film in order on a substrate; repairing interlayer short being short between the upper conductive film and the lower conductive film; and forming display elements on the wiring board. Laser light having a pulse width of 10 picoseconds or less is irradiated to a short-included region including the interlayer short in the step of repairing the interlayer short in order to remove at least the upper conductive film between the lower conductive film, the insulating film and the upper conductive film within the short-included region.

### BACKGROUND OF THE INVENTION

1. Field of the Invention

The present invention relates to a method of manufacturing a display device preferable for an organic EL (Electroluminescence) display device, a liquid crystal display device and the like, and to the display device.

2. Description of Related Art

Improvement in yield of a TFT (Thin Film Transistor) substrate is a major issue in manufacturing FPD (Flat Panel Display) at present. For example, in the case of a TFT substrate for an organic EL display device, since a plurality of electric-potential supply lines exist in addition to signal lines and scan lines, wiring density within a pixel is increased, so that a pixel structure is extremely complicated, leading to extremely high probability of defect production. On the other hand, even in the case of a TFT substrate for a liquid crystal display device, increase in size of a display device and increase in resolution of pixels are advanced on the assumption that size of the display device is increased to a level corresponding to size of a plasma display device, and the number of defects is accordingly increased, consequently significant reduction in yield is currently an important issue.

A defect occurring at a high possibility includes interlayer short. The interlayer short means a phenomenon that upper and lower conductive films are electrically connected through a defect of an insulating film or contamination of a non-insulative foreign substance at a position where the upper and lower conductive films intersect or overlap with each other. Such interlayer short generally occurs, for example, in an intersection between wiring lines or in a capacitor holding electric charges, and particularly occurs in the capacitor at a high possibility in the case of the organic EL display device. The reason for this is that capacitor area is extremely large in the organic EL display device compared with the liquid crystal display device due to difference in drive method from the liquid crystal display device. When interlayer short occurs in the capacitor, part of pixels do not emit light, or part of pixels emit excessively bright light compared with peripheral pixels, leading to extreme reduction in image display performance.

Management of a manufacturing process, such as decreasing foreign substances, is attempted to suppress such defect production. However, the defect production is hard to be perfectly avoided. Therefore, a step of repairing a defect (repair step) is currently necessary in manufacturing of a TFT substrate. For example, Japanese Unexamined Patent Application, Publication No. 2001-77198 (JP-A-2001-77198) and Japanese Unexamined Patent Application, Publication No. 11-282010 (JP-A-11-282010) disclose a method of repairing interlayer short by laser irradiation respectively.

### SUMMARY OF THE INVENTION

However, in the method of JP-A-2001-77198, one of upper and lower lines is cut by laser irradiation, and then a bypass line is formed, leading to a complicated process. In the method of JP-A-11-282010, one of upper and lower lines is cut by laser irradiation, and then the lines are reconnected to a previously provided, redundant line, leading to a difficulty that a space for the redundant line is hardly ensured in a wiring board of the organic EL display device originally having high wiring density.

Furthermore, both the methods of JP-A-2001-77198 and JP-A-11-282010 relate to defect repair in an intersection between wiring lines, and a method of repairing a defect in a capacitor has not been developed in the past.

It is desirable to provide a method of manufacturing a display device in which interlayer short formed in a capacitor in a wiring board or in an intersection between wiring lines may be repaired, and a display device in which defective display caused by the interlayer short in the capacitor in the wiring board may be suppressed.

A method of manufacturing a display device according to an embodiment of the invention includes steps of forming a wiring board having a lower conductive film, an insulating film and an upper conductive film in order on a substrate, repairing interlayer short being short between the upper conductive film and the lower conductive film, and forming display elements on the wiring board, wherein laser light having a pulse width of 10 picoseconds or less is irradiated to a short-included region including the interlayer short in the step of repairing the interlayer short in order to remove at least the upper conductive film between the lower conductive film, the insulating film and the upper conductive film within the short-included region.

A display device according to an embodiment of the invention includes a wiring board having a lower conductive film, an insulating film and an upper conductive film in order on a substrate, and display elements formed on the wiring board, wherein the wiring board includes pixel drive circuits, each pixel drive circuit having transistors including the lower conductive film, the insulating film and the upper conductive film each, and a capacitor including the lower conductive film, the insulating film and the upper conductive film, and the display elements, and the capacitor has an opening where at least the upper conductive film is removed between the lower conductive film, the insulating film and the upper conductive film.

According to the display device of the embodiment of the invention, in the opening of the capacitor in the wiring board, at least the upper conductive film is removed between the lower conductive film, the insulating film and the upper conductive film, and thus the interlayer short formed during the manufacturing process is securely repaired. This therefore suppresses defective display caused by the interlayer short in the capacitor, for example, suppresses a phenomenon that part of pixels do not emit light, or part of pixels emit excessively bright light compared with peripheral pixels.

According to the method of manufacturing a display device of the embodiment of the invention, the laser light having the pulse width of 10 picoseconds or less is irradiated to the short-included region including the interlayer short in the step of repairing interlayer short in order to remove at least an upper conductive film between a lower conductive film, an insulating film and the upper conductive film within the short-included region, therefore interlayer short formed in the capacitor in the wiring board or in the intersection between wiring lines may be repaired.

According to the display device of the embodiment of the invention, since the capacitor in the wiring board has the opening where at least the upper conductive film is removed between the lower conductive film, the insulating film and the upper conductive film, defective display caused by the interlayer short in the capacitor may be suppressed.

Other and further objects, features and advantages of the invention will appear more fully from the following description.

### BRIEF DESCRIPTION OF THE DRAWINGS

FIG. 1 is a diagram showing a configuration of a display device according to a first embodiment of the invention.

FIG. 2 is a plan view showing an example of a pixel drive circuit shown in FIG. 1.

FIG. 3 is a section view showing a configuration of a capacitor shown in FIG. 2.

FIG. 4 is a section view showing another configuration of the capacitor shown in FIG. 2.

FIG. 5 is a diagram showing an equivalent circuit of a pixel drive circuit shown in FIG. 2.

FIG. 6 is a section view showing a configuration of a display region shown in FIG. 1.

FIGS. 7A and 7B are a plan view and a section view showing a method of manufacturing the display device shown in FIG. 1 in a process sequence.

FIG. 8 is a view showing a configuration of a repair device repairing interlayer short shown in FIGS. 7A and 7B.

FIG. 9 is a plan view showing a configuration of a local repair section shown in FIG. 8 as viewed from a bottom of the section.

FIG. 10 is a plan view showing a step following the step of FIGS. 7A and 7B.

FIG. 11 is a diagram showing a relationship between pulse width and thermal diffusion length of aluminum (Al) being a main componential material of an upper conductive film (upper electrode).

FIGS. 12A and 12B are section views showing steps following the step of FIG. 10 respectively.

FIGS. 13A and 13B are section views showing steps following the steps of FIGS. 12A and 12B respectively.

FIGS. 14A and 14B are views for illustrating steps following the steps of FIGS. 13A and 13B respectively.

FIG. 15 is a plan view showing an example of a pixel drive circuit of a display device according to a second embodiment of the invention.

FIG. 16 is a section view showing a configuration of a capacitor shown in FIG. 15.

FIG. 17 is a section view showing another configuration of the capacitor shown in FIG. 15.

FIG. 18 is a chart for illustrating a method of manufacturing the display device shown in FIG. 15.

FIG. 19 is a view for illustrating steps shown in FIG. 18.

FIG. 20 is a plan view showing an example of a pixel drive circuit of a display device according to a third embodiment of the invention.

FIG. 21 is a section view showing a configuration of an interconnection shown in FIG. 20.

FIG. 22 is a section view showing another configuration of the interconnection shown in FIG. 20.

FIGS. 23A and 23B are a plan view and a section view for illustrating a method of manufacturing the display device shown in FIG. 19 in a process sequence.

FIG. 24 is a view for illustrating a step following the steps of FIGS. 23A and 23B.

FIG. 25 is a plan view showing an example of a pixel drive circuit of a display device according to a fourth embodiment of the invention.

FIG. 26 is a section view showing a configuration of an interconnection shown in FIG. 25.

FIG. 27 is a section view showing another configuration of the interconnection shown in FIG. 25.

FIG. 28 is a plan view for illustrating a method of manufacturing the display device shown in FIG. 25.

FIGS. 29A and 29B are photographs showing a result of an example according to the invention respectively.

FIGS. 30A and 30B are photographs showing another result of the example according to the invention respectively.

FIG. 31 is a diagram showing still another result of the example according to the invention.

FIG. 32 is a plan view showing a schematic configuration of a module including the display device of each of the embodiments.

FIG. 33 is a perspective view showing appearance of application example 1 of the display device of each of the embodiments.

FIG. 34A is a perspective view showing appearance of application example 2 as viewed from a surface side, and FIG. 34B is a perspective view showing appearance of the application example 2 as viewed from a back side.

FIG. 35 is a perspective view showing appearance of application example 3.

FIG. 36 is a perspective view showing appearance of application example 4.

FIG. 37A is a front view of application example 5 in an opened state, FIG. 37B is a side view of the application example, FIG. 37C is a front view thereof in a closed state, FIG. 37D is a left side view thereof, FIG. 37E is a right side view thereof, FIG. 37F is a top view thereof, and FIG. 37G is a bottom view thereof.

### DETAILED DESCRIPTION OF THE PREFERRED EMBODIMENTS

Hereinafter, preferred embodiments of the invention will be described in detail with reference to drawings. Description is made in the following sequence.

1. First embodiment (capacitor; an example of irradiating laser to a short-included region)

2. Second embodiment (capacitor; an example of determining size of interlayer short, and irradiating laser to a frame region enclosing the interlayer short)

3. Third embodiment (intersection between lines; an example of irradiating laser to a short-included region)

4. Fourth embodiment (intersection between lines; an example of irradiating laser to a frame region enclosing an interlayer defect)

5. Examples

### First Embodiment

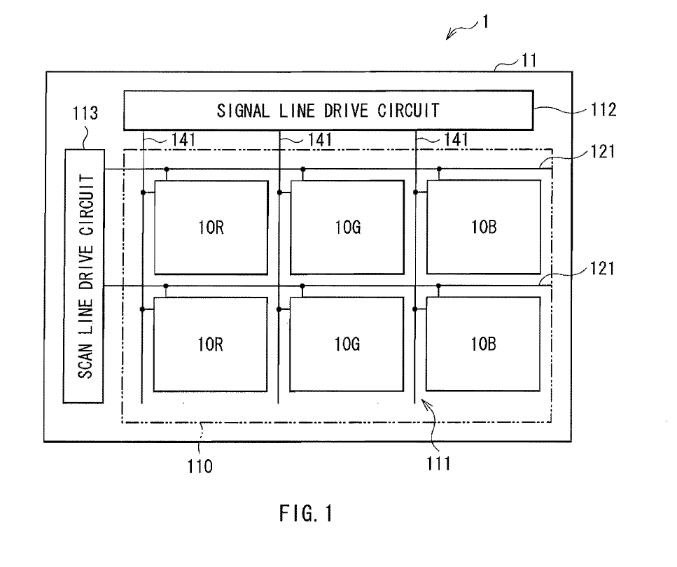

FIG. 1 shows a configuration of a display device according to a first embodiment of the invention. The display device is used for an ultra-thin organic light emitting, color display device or the like, and, for example, has a plurality of organic light emitting elements 10R, 10G and 10B described later as light emitting elements on a wiring board 1. The organic light emitting elements 10R, 10G and 10B are arranged in a matrix pattern within a display region 110 in the center of the wiring board 1.

In the wiring board 1, a pixel drive circuit 111 are formed within the display region 110 on a substrate 11, and a signal line drive circuit 112 and a scan line drive circuit 113 being a driver for picture display each are formed in the periphery of the display region 110.

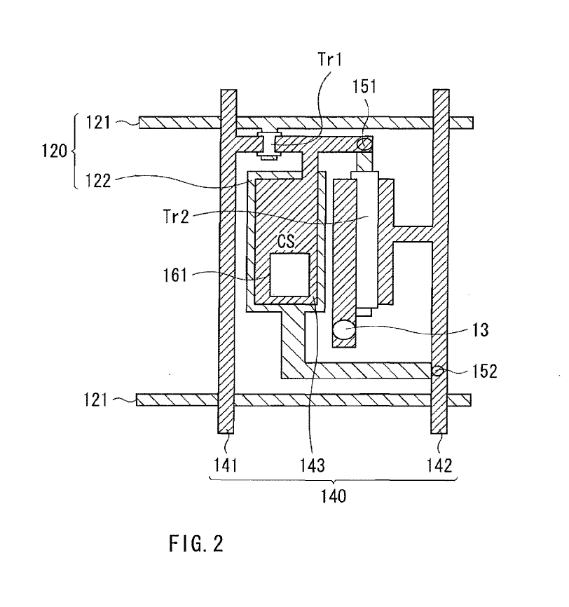

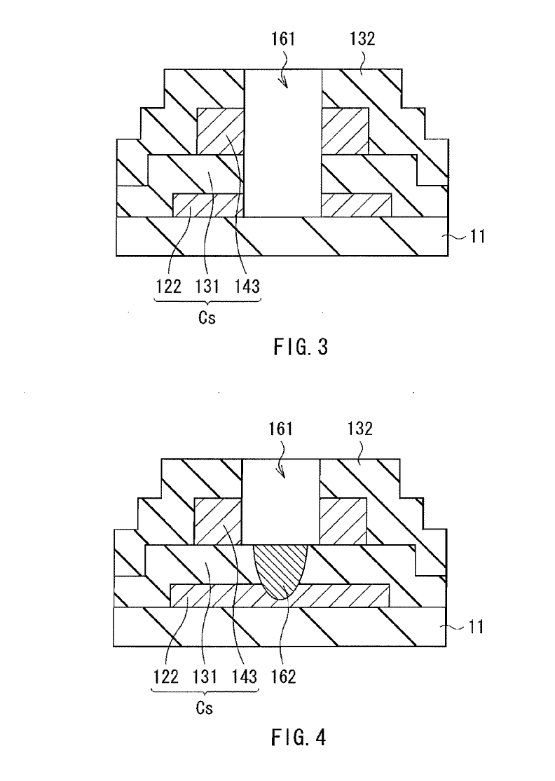

FIG. 2 shows an example of a planar configuration of the pixel drive circuit 111. The pixel drive circuit 111 has a lower conductive film 120, an insulating film 131 (not shown in FIG. 2, refer to FIG. 3), and an upper conductive film 140 in order on the substrate 11 including glass or the like. In the specification, the lower conductive film 120 is marked with downward-sloping curves, and the upper conductive film 140 is marked with upward-sloping curves in plan views of FIG. 2 and others in order to facilitate discrimination between the lower conductive film 120 and the upper conductive film 140.

The lower conductive film 120 includes each scan line 121 and lines connected thereto, namely, lines to be a lower electrode 122 of a capacitor (holding capacitance) CS, and to be a gate of each of a write transistor Tr1 and a drive transistor Tr2. The lower conductive film 120 has a thickness of, for example, about 100 nm, and includes molybdenum (Mo). The insulating film 131 has a thickness of, for example, about 300 nm, and includes silicon oxide (SiO₂).

The upper conductive film 140 includes signal lines 141, and source potential supply lines 142 and lines connected thereto, namely, lines to be an upper electrode 143 of the capacitor CS, and to be a source and a drain of each of the write transistor Tr1 and the drive transistor Tr2. The upper conductive film 140 includes, for example, a stacked film of a titanium (Ti) layer 50 nm in thickness, an aluminum (Al) layer 900 nm in thickness, and a titanium (Ti) layer 50 nm in thickness, and total thickness of the stacked film is, for example, about 1000 nm.

An insulating film 132 (not shown in FIG. 2, refer to FIG. 3) may be formed on each of the lower conductive film 120, the insulating film 131, and the upper conductive film 140. The insulating film 132 has a thickness of, for example, about 300 nm, and includes silicon nitride (SiN).

FIG. 3 shows an example of a sectional configuration of the capacitor CS. The capacitor CS has an opening 161 where the upper electrode 143, the insulating film 131 and the lower electrode 122 are removed. Thus, in the display device, defective display caused by interlayer short in the capacitor CS may be suppressed.

The opening 161 is an opening left as a repair mark made in repairing interlayer short formed in the capacitor CS during a manufacturing process, and therefore need not be necessarily formed in each of capacitors CS of pixel drive circuits 111 of all organic light emitting elements 10R, 10G and 10B.

FIG. 4 shows another example of a sectional configuration of the capacitor CS. In the opening 161, only the upper electrode 143 may be removed between the upper electrode 143, the insulating film 131 and the lower electrode 122. In this case, a conductive foreign substance 162 causing interlayer short may be left in the insulating film 131 and the lower electrode 122.

In the opening 161, the upper electrode 143, the insulating film 131 and the lower electrode 122 are preferably removed as shown in FIG. 3, rather than only the upper electrode 143 as shown in FIG. 4. This is because stable and secure repair is enabled thereby. Specifically, when the lower electrode 122 is not completely removed as shown in FIG. 4, a conductive material configuring the lower electrode 122 may be diffused into the insulating film 131, leading to a possibility of short with the upper electrode 143.

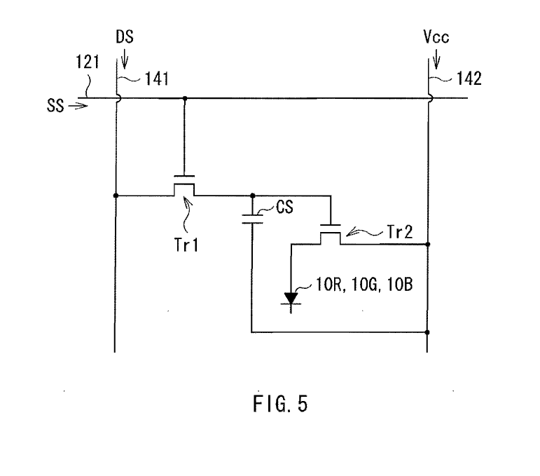

FIG. 5 shows an equivalent circuit of the pixel drive circuit 111 shown in FIG. 2. The pixel drive circuit 111 is formed under a first electrode 13 described later, and is an active drive circuit having the write transistor Tr1, the drive transistor Tr2, and the capacitor (holding capacitance) Cs between the transistors, and an organic light emitting element 10R (10G or 10B) connected to the source potential supply line 142 via the drive transistor Tr2.

A gate of the write transistor Tr1 is connected to the scan line 121. One of the source and drain of the write transistor Tr1 is connected to the signal line 141, and the other is connected to the upper electrode 133 of the capacitor CS and to the gate of the drive transistor Tr2 via a connection hole 151. The lower electrode 122 of the capacitor CS is connected to the source potential supply line 142 via a connection hole 152. One of the source and drain of the drive transistor Tr2 is connected to the source potential supply line 142, and the other is connected to the first electrode 13 described later of the organic light emitting element 10R (10G or 10B).

The scan lines 121 are mainly provided in a row direction, and signal lines 141 and the source potential supply lines 142 are mainly provided in a column direction (direction perpendicular to the scan lines 121). An intersection between each signal line 141 and each scan line 121 corresponds to one pixel, namely, one of the organic light emitting elements 10R, 10G and 10B. Each signal line 141 is connected to the signal line drive circuit 112, and an image signal DS is supplied from the signal line drive circuit 112 to a source electrode of the write transistor Tr1 via the signal line 141. Each scan line 121 is connected to the scan line drive circuit 113, and scan signals SS are sequentially supplied from the scan line drive circuit 113 to a gate electrode of the write transistor Tr1 via the scan line 121.

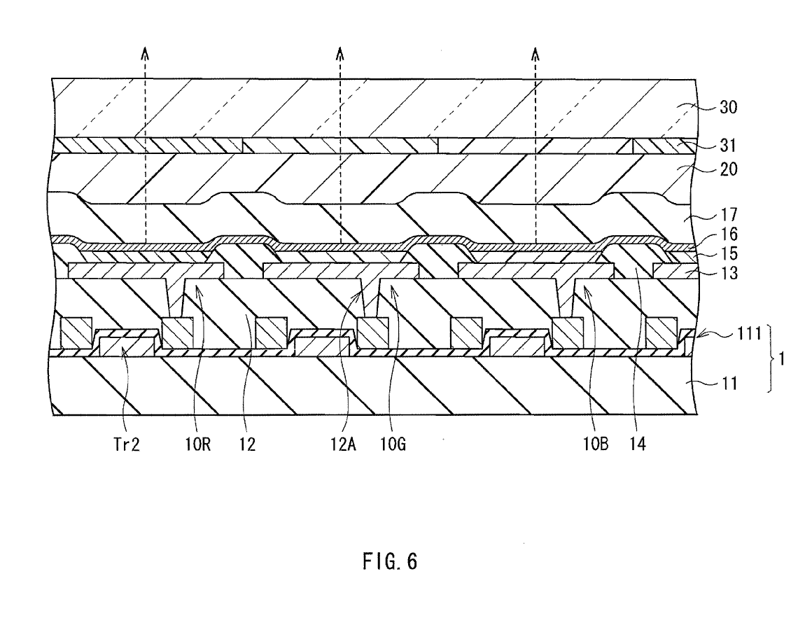

FIG. 6 shows a sectional configuration of the display region 110. In the display region 110, the organic light emitting elements 10R emitting red light, the organic light emitting elements 10G emitting green light, and the organic light emitting elements 10B emitting blue light are formed in turn generally in a matrix pattern. The organic light emitting elements 10R, 10G and 10B have, for example, a strip-like (rectangular) planar-shape each, and are arranged in lines in a longitudinal direction for each emission light color. A combination of organic light emitting elements 10R, 10G and 10B adjacent to one another configures one pixel.

Each of the organic light emitting elements 10R, 10G and 10B has a configuration where the drive transistor Tr2 of the pixel drive circuit 111, a planarization layer 12, the first electrode 13 as an anode, an insulating film 14, an organic layer 15 including a light emitting layer described later, and a second electrode 16 as a cathode are stacked in this order from a substrate 11 side.

As necessary, such organic light emitting elements 10R, 10G and 10B are covered by a protective film 17 such as silicon nitride (SiN) or silicon oxide (SiO), and furthermore, a seal substrate 30 including glass or the like is adhered onto the whole surface of the protective film 17 with an adhesion layer 20 including thermosetting resin or ultraviolet curing resin in between in order to seal the light emitting elements. A color filter 31 and a light shielding film (not shown) as a black matrix may be provided on the seal substrate 30 as necessary.

The drive transistor Tr2 is electrically connected to the first electrode 13 via a connection hole 12A provided in the planarization layer 12. The planarization layer 12 flattens a surface of the wiring board 1 having the pixel drive circuit 111 and the like formed thereon, and preferably includes a material providing high pattern accuracy because fine connection holes 12A are formed therein. A componential material of the planarization layer 12 includes, for example, an organic material such as polyimide, or an inorganic material such as silicon oxide (SiO₂).

The first electrode 13 is formed in correspondence to each of the organic light emitting elements 10R, 10G and 10B. The first electrode 13 further has a function of a reflective layer, and includes metal such as platinum (Pt), gold (Au), silver (Ag), chromium (Cr) or tungsten (W), or metal alloy thereof. The insulating film 14 ensures isolation between the first electrode 13 and the second electrode 16, and accurately makes a shape of a light emitting region of each of the organic light emitting elements 10R, 10G and 10B to be a desired shape, and includes, for example, polyimide.

For example, the organic layer 15 has a structure where, a hole transport layer, a light emitting layer, and an electron transport layer are stacked in this order from a first electrode 13 side. The hole transport layer improves hole injection efficiency into the light emitting layer. The light emitting layer is applied with a voltage, thereby recombination of an electron and a hole occurs, leading to light generation. The electron transport layer improves electron injection efficiency into the light emitting layer. A componential material of the hole transport layer of the organic light emitting element 10R includes, for example, bis[(N-naphtyl)-N-phenyl]benzidine (α-NPD), a componential material of the light emitting layer of the organic light emitting element 10R includes, for example, 2, 5-bis-[4-[N-(4-methoxyphenyl)-N-phenylamino]] styrilbenzene-1, 4-dicarbonitrile (BSB), and a componential material of the electron transport layer of the organic light emitting element 10R includes, for example, 8-quinolinol aluminum complex (Alq₃). A componential material of the hole transport layer of the organic light emitting element 10B includes, for example, α-NPD, a componential material of the light emitting layer of the organic light emitting element 10B includes, for example, 4,4′-bis(2,2′-diphenylvinylene) biphenyl (DPVBi), and a componential material of the electron transport layer of the organic light emitting element 10B includes, for example, Alq₃. A componential material of the hole transport layer of the organic light emitting element 10G includes, for example, α-NPD, a componential material of the light emitting layer of the organic light emitting element 10G includes, for example, Alq₃ mixed with coumarin 6 (C6) of 1 vol %, and a componential material of the electron transport layer of the organic light emitting element 10G includes, for example, Alq₃.

The second electrode 16 includes a semitransparent electrode, and light generated in the light emitting layer is extracted from a second electrode 16 side. The second electrode 16 includes metal such as silver (Ag), aluminum (Al), magnesium (Mg), calcium (Ca) or potassium (Na), or metal alloy thereof.

The display device may be manufactured, for example, in the following way.

Step of Forming Wiring Board

First, the substrate 11 including the above material is prepared, and a molybdenum film is formed by about 100 nm, and then shaped into a predetermined pattern by photolithography. Thus, the lower conductive film 120 is formed, the conductive film including each scan line 121 and the lines connected thereto, namely, the lines to be the lower electrode 122 of the capacitor CS, and the gate of each of the write transistor Tr1 and the drive transistor Tr2. At that time, the lower electrode 122 may be adhered with the conductive foreign substance 162.

Next, the insulating film 131 having the above thickness and including the above material is formed on the lower conductive film 120. At that time, the foreign substance 162 is not necessarily wholly covered by the insulating film 131, and may be partially exposed from the insulating film 131.

Next, a stacked film of a titanium (Ti) layer, an aluminum (Al) layer, and a titanium (Ti) layer is formed with a total thickness of about 1000 nm on the insulating film 131, and then shaped into a predetermined pattern by photolithography. Thus, the upper conductive film 140 is formed, the conductive film including each signal line 141, and each source potential supply line 142 and lines connected thereto, namely, lines to be the upper electrode 143 of the capacitor CS, and the source and the drain of each of the write transistor Tr1 and the drive transistor Tr2. Thus, the wiring board 1 having the pixel drive circuit 111 on the substrate 11 is formed. The signal line drive circuit 112 and the scan line drive circuit 113 may be formed by the same process as in the pixel drive circuit 111.

Step of Repairing Interlayer Short

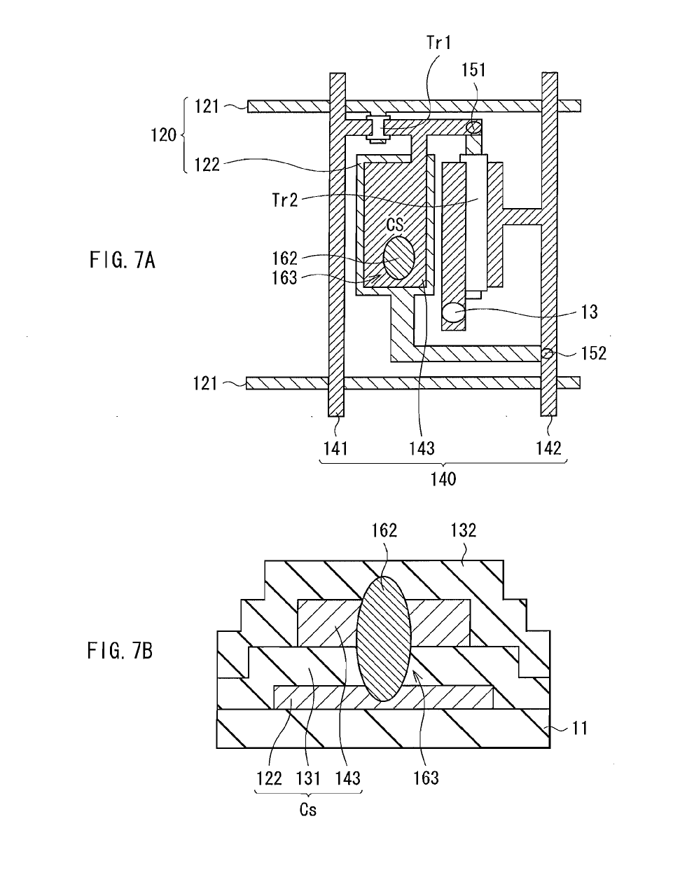

In the process, interlayer short 163, where the lower electrode 122 is shorted with the upper electrode 143 via the foreign substance 162, may occur in the capacitor CS as shown in FIGS. 7A and 7B. Therefore, presence of the interlayer short 163 is checked by, for example, an electrical test, and then a position or size of the interlayer short is extracted by an optical test. The electrical test may be performed by, for example, a charge detection method using an array tester (electrical glass substrate tester). In the charge detection method, all pixels are written with charges in approximately the same way as in actual operation, and the written charges are read after certain elapsed time, and defectiveness of each pixel is determined from transition of the charges. In the optical test, a position and size of the interlayer short 163 are checked, for example, by pattern inspection. The pattern inspection is performed in such a way that the pixel drive circuit 111 is magnified by a spectroscope, and the magnified image is taken by a CCD (Charge Coupled Device) camera or the like, and abnormality is detected by image processing in which difference in image is evaluated between adjacent pixels, and when a significant difference is found, the relevant pixel is determined to be defective. A cause of the interlayer short 163 may include a defect of the insulating film 131 in addition to a defect produced in the photolithography step due to the conductive foreign substance 162 as above.

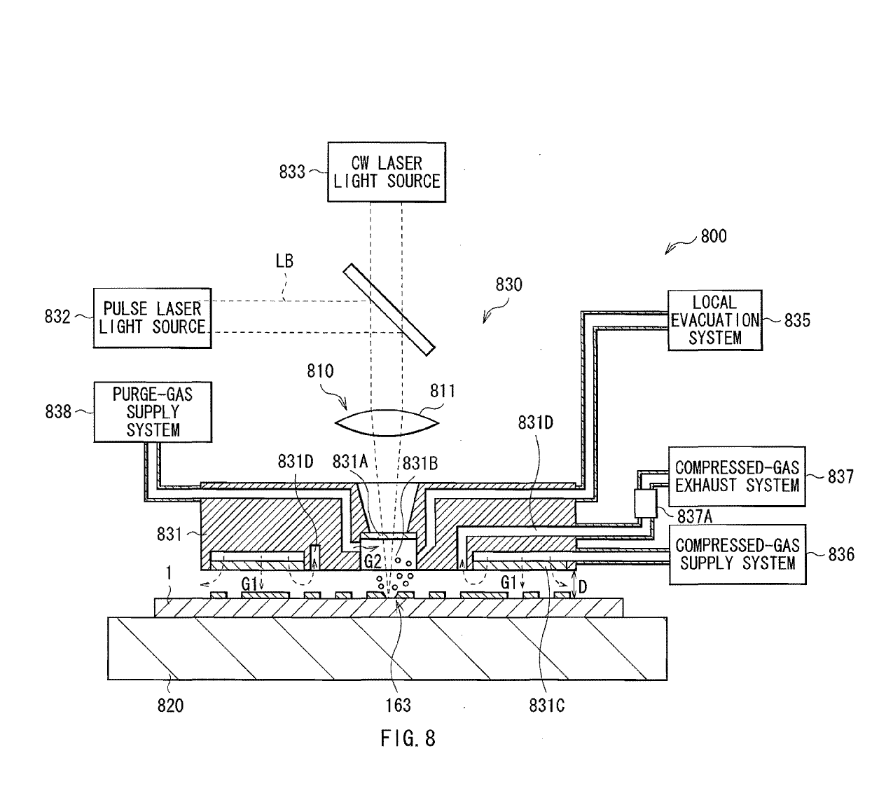

Then, the interlayer short 163 is repaired by a repair device. FIG. 8 shows a configuration of a repair device 800. The repair device 800 includes, for example, an optical system 810 for observing the interlayer short 163, a movement mechanism 820 relatively moving the optical system 810 to the wiring board 1, and a repair mechanism 830 for repairing the interlayer short 163. The optical system 810 includes, for example, an objective lens 811. The movement mechanism 820 includes, for example, an X-Y stage.

The repair mechanism 830 has, for example, a local repair section 831 provided between the wiring board 1 on the movement mechanism 820 and the objective lens 811. The local repair section 831 has a window 831A and a laser irradiation room 831B below the objective lens 811, and the interlayer short 163 may be observed through the window 831A, or laser light LB may be irradiated to perform a repair step therethrough.

The repair mechanism 830 further has a pulse laser light source 832 for laser processing, a CW (Continuous Wave) laser light source 833 for a laser CVD process, a local evacuation system 835, a compressed-gas supply system 836, a compressed-gas exhaust system 837, and a purge-gas supply system 838.

The pulse laser light source 832 may generate laser light LB having a pulse width of 10 picoseconds or less. The local evacuation system 835 locally evacuates the laser irradiation room 831B to discharge a wiring material removed by laser processing. The compressed-gas supply system 836 flies the local repair section 831 by using a compressed gas G1 including an inactive gas such as argon (Ar) or nitrogen (N₂). The compressed-gas exhaust system 837 exhausts the compressed gas G1 and thereby forms a spring having an extremely large spring constant between the local repair section 831 and the wiring board 1 so that variation in flying height D of the local repair section 831 is suppressed to increase stiffness of flying. The purge-gas supply system 838 blows a purge gas G2 such as argon (Ar) gas to the window 831A to suppress adhesion of the wiring material removed by laser processing to the window. The repair mechanism 830 may have a deposition material supply system supplying a gas for the laser CVD process, or a coating liquid supply system for a metal particle coating process (both systems are not shown) as necessary.

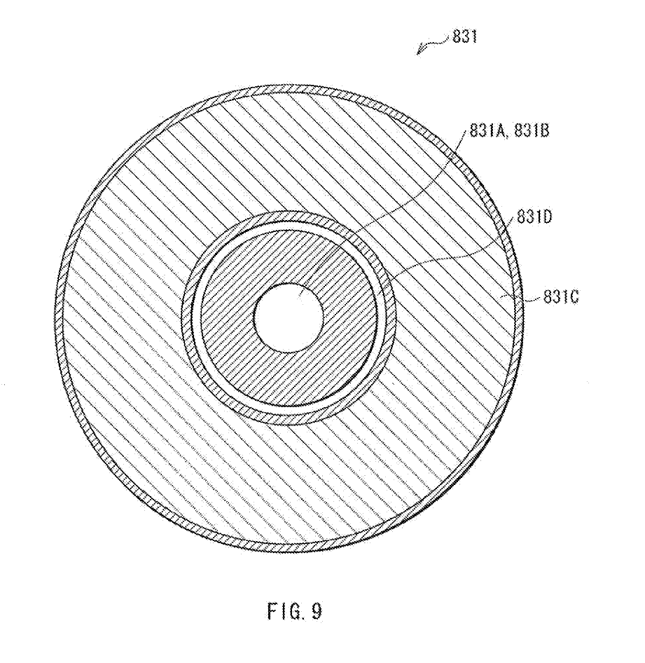

As shown in FIG. 9, a bottom of the local repair section 831 has an air blow section 831C including porous aluminum for blowing the compressed gas G1 including nitrogen (N₂) or the like, and a compressed-gas suction hole 831D for exhausting the compressed gas G1 flowing into a region near an irradiation position of the laser light LB. The air blow section 831C flies the local repair section 831 with respect to the wiring board 1 by the compressed gas G1. The compressed gas suction hole 831D sucks the compressed gas G1, and exhausts the gas through the compressed-gas exhaust system 837.

The repair device 800 may repair the interlayer short 163, for example, in the following way.

First, the local repair section 831 is preferably beforehand flown by, for example, about 100 μm before performing the repair. This is because even if warp or swell is produced on the wiring board 1, the wiring board 1 may be prevented from being contacted with the local repair section 831 and damaged. To fly the local repair section 831, for example, argon (Ar) or nitrogen (N₂) is supplied from the compressed-gas supply system 836 as compressed gas G1, and the compressed gas G1 is blown to the movement mechanism 820 via the air blow section 831C.

Moreover, the window 831A is preferably blown with nitrogen gas of 200 ccm as the purge gas G2 by the purge-gas supply system 838.

Next, the movement mechanism 820 is moved in a horizontal direction, and the wiring board 1 is thus inserted into a space between the local repair section 831 and the movement mechanism 820. Next, the compressed-gas exhaust system 837 starts exhaust, and pressure or a flow rate of the compressed gas G1 is controlled by the valve 837A so that flying height D of the local repair section 831 is adjusted to, for example, 20 μm.

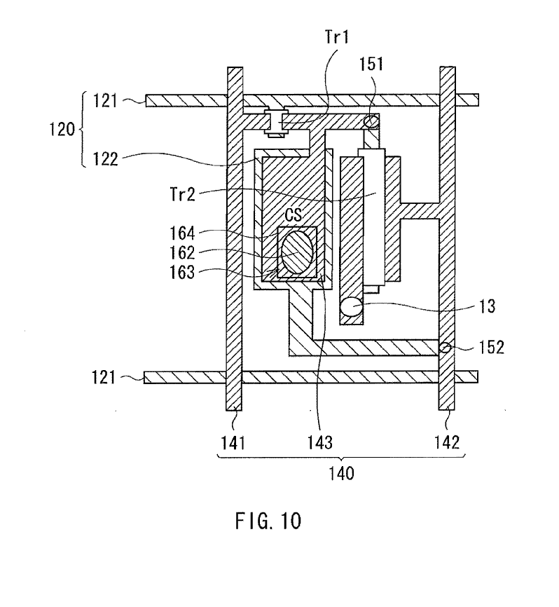

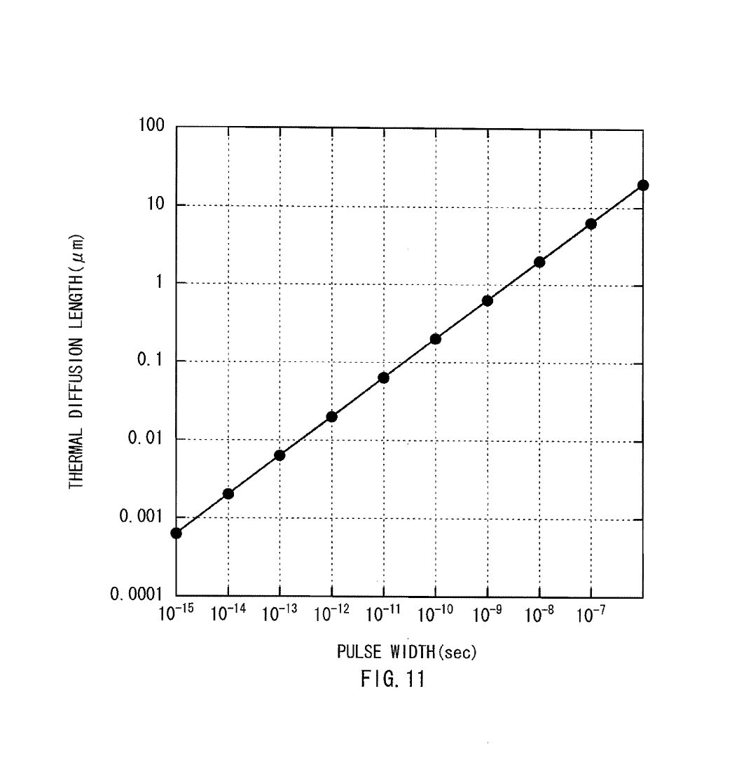

Then, as shown in FIG. 10, the laser light LB having a pulse width of 10 picoseconds or less is irradiated to a short-included region 164 including the interlayer short 163, namely, irradiated covering the interlayer short 163. FIG. 11 shows a relationship between pulse width and thermal diffusion length of aluminum (Al) being a main componential material of the upper conductive film 140 (upper electrode 143). The thermal diffusion length is expressed as thermal diffusion length [μm]=2 √thermal diffusivity [m²/sec]*pulse width [sec]. Thermal diffusivity of aluminum is assumed to be 9.98*10⁻⁴ m²/sec. The thermal diffusion length is desirably adjusted to 0.1 μm or less to prevent short between the upper conductive film 140 (upper electrode 143) and the lower conductive film 120 (lower electrode 122). To achieve this, pulse width of the laser light LB can be adjusted to 10 picoseconds or less as known from FIG. 11.

Energy density per pulse of the laser light LB is preferably adjusted to 0.03 J/cm² to 0.5 J/cm². The reason for this is as follows. When the energy density is less than 0.03 J/cm², since the energy density is lower than a processing threshold value of a material, processing may not be performed. When the energy density is more than 0.5 J/cm², a material tends to be melted, and consequently the lower electrode 122 may be shorted with the upper electrode 143.

Specifically, the laser light LB is adjusted to be 400 nm in wavelength, 500 Hz in repetition, 3 picoseconds in pulse width, and 10 μm square in irradiation beam shape, and outputted by 4000 pulses at rest for irradiation for about 8 seconds while energy density is set to 0.2 J/cm² on a surface of the wiring board 1. The laser light LB is shaped by an aperture (not shown), and irradiated while being observed using an objective lens 811 of the optical system 810 with 50 magnifications and an operation distance of 15 mm.

Thus, the lower electrode 122, the insulating film 131 and the upper electrode 143 within the short-included region 164 are removed and thus the interlayer short 163 is repaired, so that the opening 161 is formed as shown in FIGS. 2 and 3. Alternatively, only the upper electrode 143 may be removed between the lower electrode 122, the insulating film 131 and the upper electrode 143 within the short-included region 164 as shown in FIG. 4. In such a case, the laser light LB is adjusted to be 400 nm in wavelength, 500 Hz in repetition, 3 picoseconds in pulse width, and 10 μm square in irradiation beam shape, and outputted by 4000 pulses at rest for irradiation for about 8 seconds while energy density is set to 0.03 J/cm² on the surface of the wiring board 1.

Step of Forming Organic Light Emitting Elements 10R, 10G and 10B on Wiring Board 1

In this way, the interlayer short 163 in the wiring board 1 is repaired. Then, as shown in FIG. 12A, photosensitive resin is coated over the whole surface of the wiring board 1 to form the planarization layer 12, and the planarization layer is predeterminately patterned concurrently with formation of connection holes 12A by exposure and development, and then baked.

After the planarization layer 12 is formed, the first electrode 13 including the above material is formed by, for example, a sputter method, and shaped into a predetermined pattern by, for example, etching as shown in FIG. 12B.

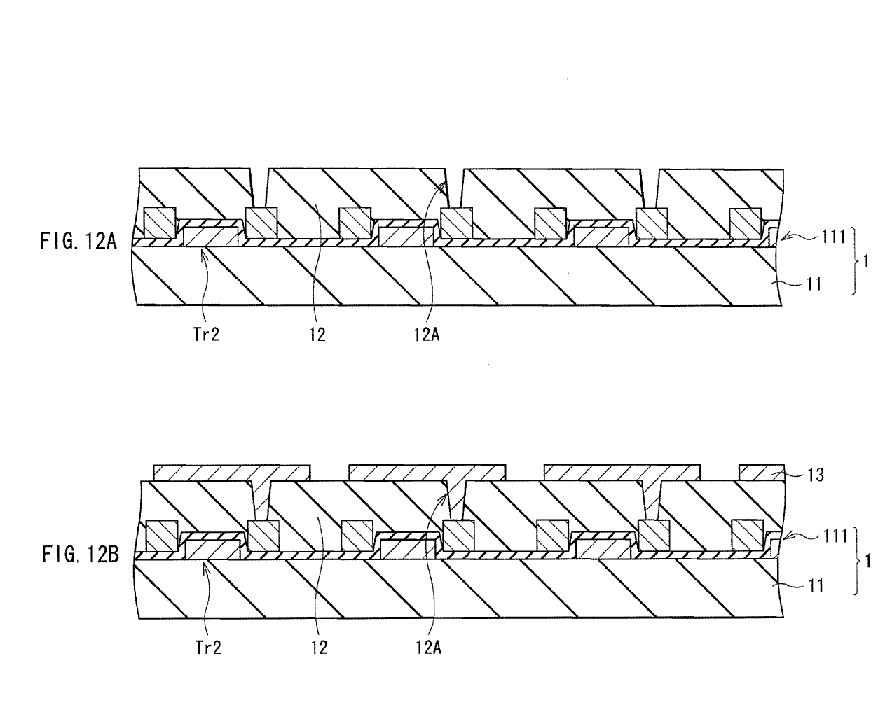

After the first electrode 13 is formed, photosensitive resin is coated over the whole surface of the planarization layer 12, then openings are formed in correspondence to the light emitting regions by, for example, photolithography, and then the photosensitive resin is baked, so that the insulating film 14 is formed as shown in FIG. 13A.

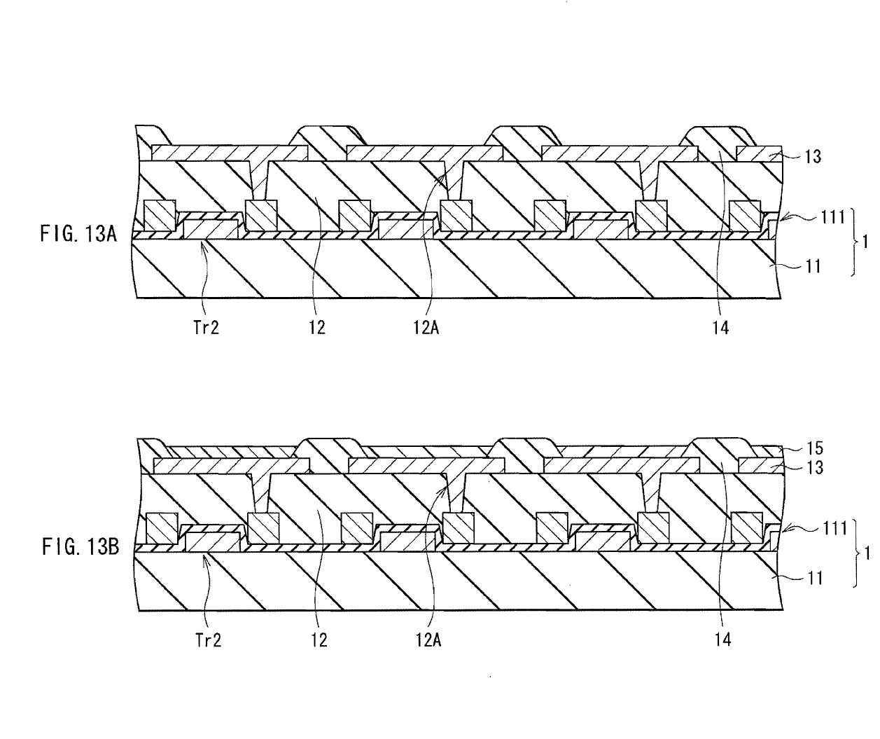

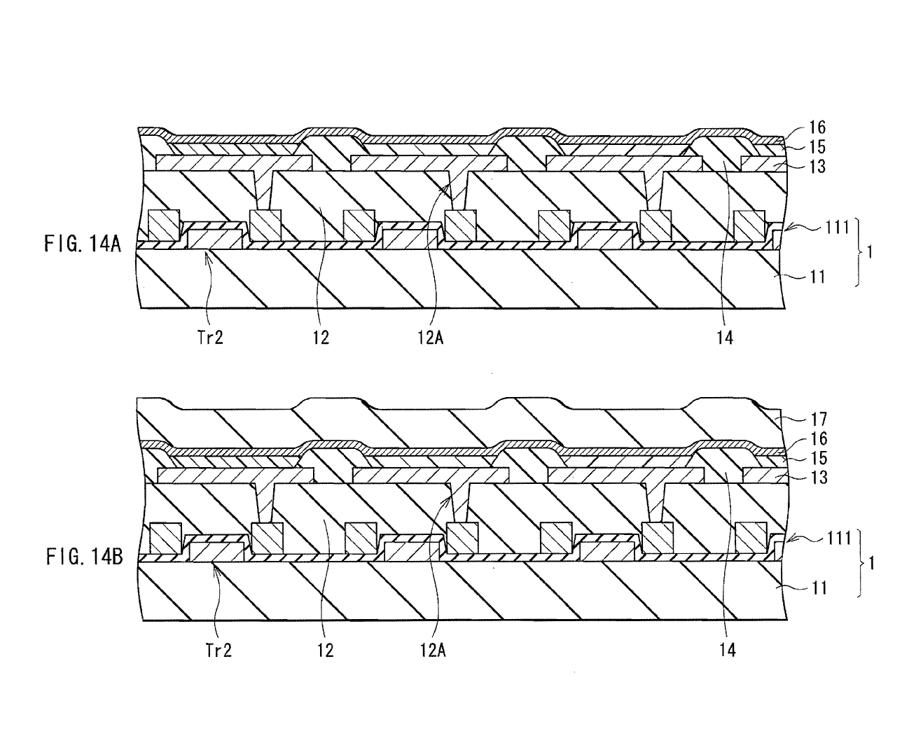

After the insulating film 14 is formed, the organic layer 15 including the hole injection layer, the hole transport layer, the light emitting layer, the electron transport layer, and the electron injection layer, each layer having the above thickness and including the above material, and the second electrode 16 are sequentially formed as shown in FIG. 13B and FIG. 14A. Thus, the organic light emitting elements 10R, 10G and 10B are formed.

After the organic light emitting elements 10R, 10G and 10B are formed, the protective film 17 including the above material is formed by, for example, an evaporation method or a CVD method as shown in FIG. 14B.

Moreover, a material of a red filter is coated by spin coating or the like on the seal substrate 30 including the above material, then the coated material is patterned by a photolithography technique and baked, thereby the red filter is formed. Next, a blue filter and a green filter are sequentially formed in the same way as in the red filter, leading to formation of the color filter 31.

Then, the adhesion layer 20 is formed on the protective film 17, and then the seal substrate 30 is adhered to the protective film 17 with the adhesion layer 20 in between. Thus, the display device shown in FIGS. 1 to 6 is completed.

In the display device obtained in this way, the scan signal SS is supplied from the scan line drive circuit 113 to each pixel via the gate electrode of the write transistor Tr1, and the image signal DS is supplied from the signal line drive circuit 112 to the holding capacitance CS via the write transistor Tr1, and held by the holding capacitance CS. Specifically, the drive transistor Tr2 is controlled to be on or off in accordance with the signal held by the holding capacitance CS, and thus a drive current is injected into each of the organic light emitting elements 10R, 10G and 10B, and recombination of a hole with an electron thus occurs, leading to light emission. The emitted light is transmitted by the second electrode 16, the color filter 31 and the seal substrate 30, and then extracted.

In this way, in the method of manufacturing the display device according to the embodiment, the laser light LB having a pulse width of 10 picoseconds or less is irradiated to the short-included region 164 including the interlayer short 163 in the step of repairing the interlayer short 163 in order to remove at least the upper electrode 143 between the lower electrode 122, the insulating film 131 and the upper electrode 143 within the short-included region 164, therefore the interlayer short 163 formed in the capacitor CS in the wiring board 1 may be repaired.

Particularly, the lower electrode 122, the insulating film 131 and the upper electrode 143 within the short-included region 164 are removed, leading to stable and secure repair.

According to the display device of the embodiment, since the capacitor CS in the wiring board 1 has the opening 161 where at least the upper electrode 143 is removed between the lower electrode 122, the insulating film 131 and the upper electrode 143, defective display caused by the interlayer short 163 in the capacitor CS may be suppressed.

### Second Embodiment

FIG. 15 shows an example of a planar configuration of a pixel drive circuit 111 of a display device according to a second embodiment of the invention. The display device has the same configuration as in the first embodiment except that a capacitor CS has a groove 165. Therefore, corresponding components are described with the same reference numerals or signs.

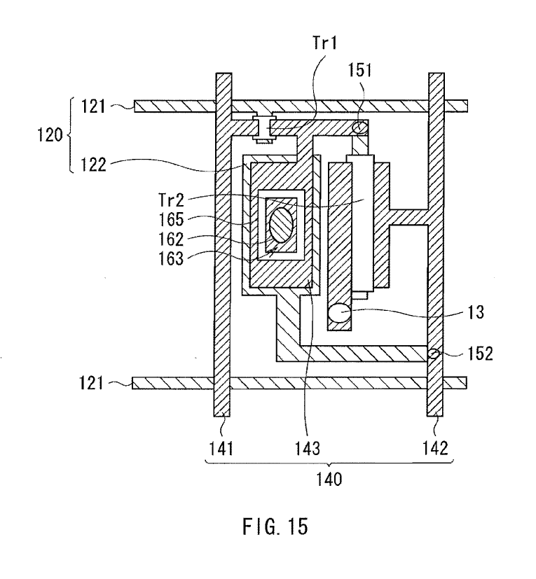

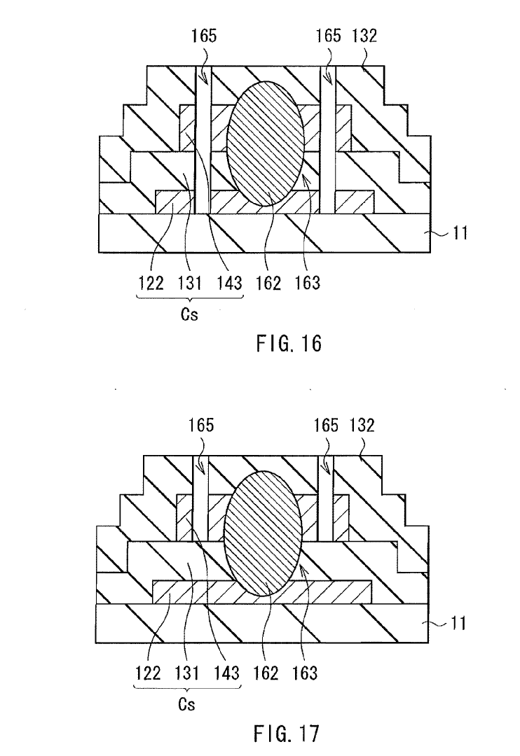

FIG. 16 shows an example of a sectional configuration of the capacitor CS. In the capacitor CS, interlayer short 163 is directly left, and the groove 165 encloses the interlayer short 163. In the groove 165, an upper electrode 143, an insulating film 131 and a lower electrode 122 are removed. Thus, in the display device, defective display caused by the interlayer short in the capacitor CS may be suppressed as in the first embodiment.

The groove 165 is a groove left as a repair mark made in repairing interlayer short formed in the capacitor CS during a manufacturing process, and therefore need not be necessarily formed in each of capacitors CS of pixel drive circuits 111 of all organic light emitting elements 10R, 10G and 10B.

FIG. 17 shows another example of a sectional configuration of the capacitor CS. In the groove 165, only the upper electrode 143 may be removed between the upper electrode 143, the insulating film 131 and the lower electrode 122 as in the opening 161. In this case, a conductive foreign substance 162 causing interlayer short may be left in the insulating film 131 and the lower electrode 122.

In the groove 165, the upper electrode 143, the insulating film 131 and the lower electrode 122 are preferably removed as shown in FIG. 16, rather than only the upper electrode 143 as shown in FIG. 17. This is because stable and secure repair is enabled thereby.

The groove 165 and the opening 161 may be combined in the same wiring board 1 or the same display device. In such a case, the groove 165 and the opening 161 are preferably properly used depending on size of the interlayer short 163 as described in the following manufacturing method.

The display device may be manufactured, for example, in the following way.

Step of Forming Wiring Board

First, a lower conductive film 120, the insulating film 131, and an upper conductive film 140 are formed on a substrate 11 according to the step shown in FIGS. 7A and 7B, so that a wiring board 1 is formed as in the first embodiment.

Step of Repairing Interlayer Short

Next, presence of the interlayer short 163 is checked by, for example, an electrical test, and then a position or size of the interlayer short is extracted by an optical test as in the first embodiment (step S101).

Then, the interlayer short 163 is repaired by using the repair device shown in FIGS. 8 and 9. At that time, a method of irradiating laser light LB is preferably varied depending on size of the interlayer short 163. This is because the interlayer short 163 may be securely repaired thereby regardless of size of the interlayer short.

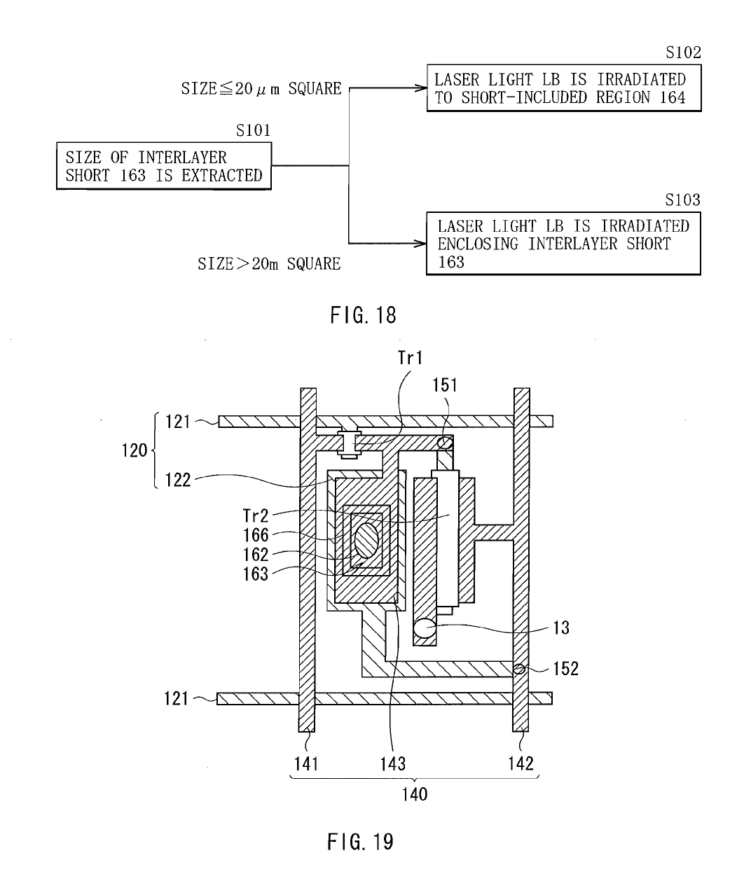

Specifically, as shown in FIG. 18, a certain threshold value (for example, 20 μm square) is set for size of the interlayer short 163, and whether size of the interlayer short 163 is not larger than or larger than the threshold value is determined. When size of the interlayer short 163 is not larger than the threshold value (20 μm square or smaller), the laser light LB is preferably irradiated to the short-included region 164 (step S102). This is because processing area may be minimized, and process time may be reduced since the laser light LB may be irradiated at rest. In this case, a repair method is the same as in the first embodiment.

In contrast, when size of the interlayer short 163 is larger than the threshold value (larger than 20 μm square), the laser light LB is preferably irradiated to a frame region 166 enclosing the interlayer short 163 (step S103). This is because when size of the interlayer short 163 is large, slit size for adjusting a beam shape of the laser light LB may not meet the size, or even if the slit size meets the size, laser energy distribution in an irradiation plane becomes irregular, leading to reduction in repair reliability.

In this case, for example, the laser light LB is adjusted to be 400 nm in wavelength, 500 Hz in repetition, 3 picoseconds in pulse width, and 8 μm square in irradiation beam shape, and the pulsed laser light LB is irradiated by 6 scans by a scanning method with scan speed of 5 μm/sec while energy density is set to 0.2 J/cm² on a surface of the wiring board 1.

Thus, the lower electrode 122, the insulating film 131 and the upper electrode 143 within the frame region 166 are removed, so that the interlayer short 163 is separated from the capacitor CS, and consequently the groove 165 is formed as shown in FIGS. 15 and 16.

Alternatively, only the upper electrode 143 may be removed between the lower electrode 122, the insulating film 131 and the upper electrode 143 within the frame region 166 as shown in FIG. 17. In such a case, for example, the laser light LB is adjusted to be 400 nm in wavelength, 500 Hz in repetition, 3 picoseconds in pulse width, and 8 μm square in irradiation beam shape, and the pulsed laser light LB is irradiated by 6 scans by the scanning method with scan speed of 5 μm/sec while energy density is set to 0.03 J/cm² on a surface of the wiring board 1. Even in this way, the interlayer short 163 may be repaired, and the groove 165 may be formed.

Step of Forming Organic Light Emitting Elements 10R, 10G and 10B on Wiring Board 1

In this way, the interlayer short 163 in the wiring board 1 is repaired. Then, organic light emitting elements 10R, 10G and 10B are formed according to the steps shown in FIGS. 12A to 14B, so that a display device may be formed as in the first embodiment.

Operation of the display device is the same as in the first embodiment.

In this way, according to the method of manufacturing the display device of the embodiment, since a method of irradiating the laser light LB is varied depending on size of the interlayer short 163 in a step of repairing the interlayer short 163, the interlayer short 163 which is occurred in the capacitor CS in the wiring board 1 may be securely repaired regardless of size of the interlayer short.

In particular, when size of the interlayer short 163 is not larger than the threshold value, the laser light LB is irradiated to the short-included region 164. Therefore, processing area may be minimized, and process time may be reduced since the laser light LB may be irradiated at rest.

When size of the interlayer short 163 is larger than the threshold value, the laser light LB is irradiated to the frame region 166 enclosing the interlayer short 163. Therefore, even if size of the interlayer short 163 is large, reduction in repair reliability may be suppressed.

Furthermore, since the lower electrode 122, the insulating film 131 and the upper electrode 143 within the frame region 166 are removed, the interlayer short may be stably and securely repaired.

According to the display device of the embodiment, the capacitor CS in the wiring board 1 has the groove 165 where at least the upper electrode 143 is removed between the lower electrode 122, the insulating film 131 and the upper electrode 143, defective display caused by the interlayer short 163 in the capacitor CS may be suppressed.

### Third Embodiment

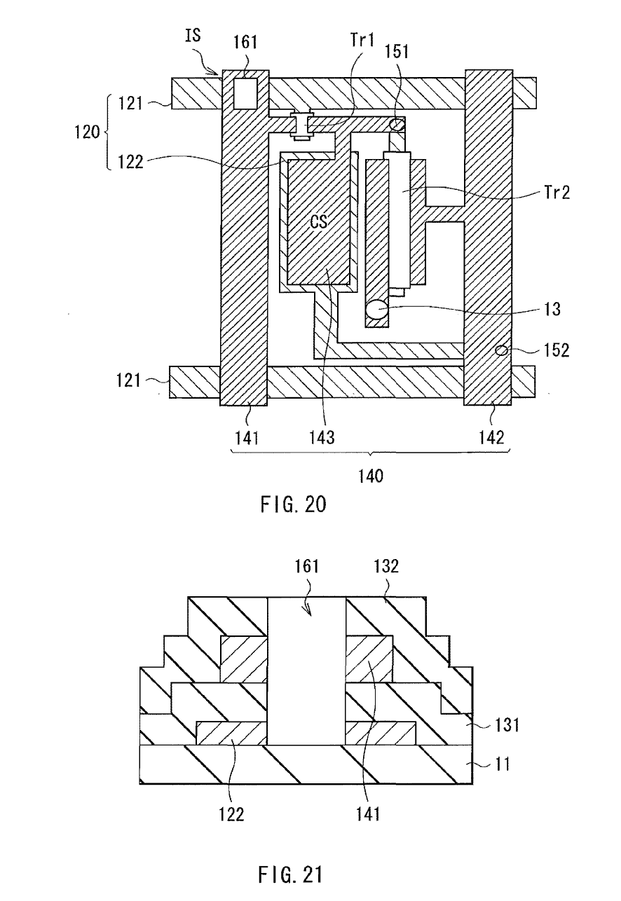

FIG. 20 shows an example of a planar configuration of a pixel drive circuit 111 of a display device according to a third embodiment of the invention. The display device has the same configuration as in the first embodiment except that an opening 161 is provided in an intersection IS between a scan line 121 and a signal line 141. Therefore, corresponding components are described with the same reference numerals or signs.

FIG. 21 shows an example of a sectional configuration of the intersection IS. In the opening 161, the signal line 141, the insulating film 131 and the scan line 121 are removed. Thus, defective display caused by the interlayer short in the intersection IS may be suppressed in the display device.

The opening 161 is an opening left as a repair mark made in repairing interlayer short formed in the intersection IS during a manufacturing process, and therefore need not be necessarily formed in each of all intersections IS.

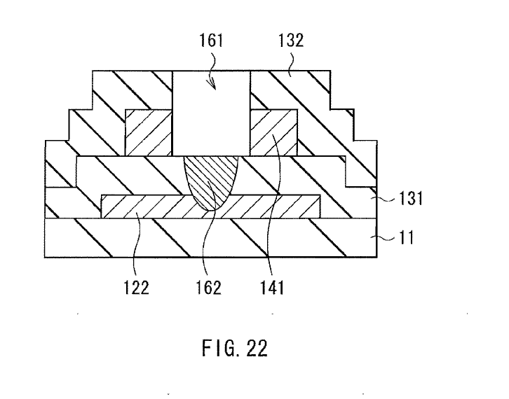

FIG. 22 shows another example of a sectional configuration of the intersection IS. In an opening, only the signal line 141 may be removed between the signal line 141, the insulating film 131 and the scan line 121 as in the first embodiment. In this case, a conductive foreign substance 162 causing interlayer short may be left in the insulating film 131 and the scan line 121.

In the opening 161, the signal line 141, the insulating film 131 and the scan line 121 are preferably removed as shown in FIG. 21, rather than only the signal line 141 as shown in FIG. 22. This is because stable and secure repair is enabled thereby.

The display device may be manufactured, for example, in the following way.

Step of Forming Wiring Board

First, a lower conductive film 120, the insulating film 131, and an upper conductive film 140 are formed on a substrate 11 according to the step shown in FIGS. 7A and 7B, so that a wiring board 1 is formed as in the first embodiment.

Step of Repairing Interlayer Short

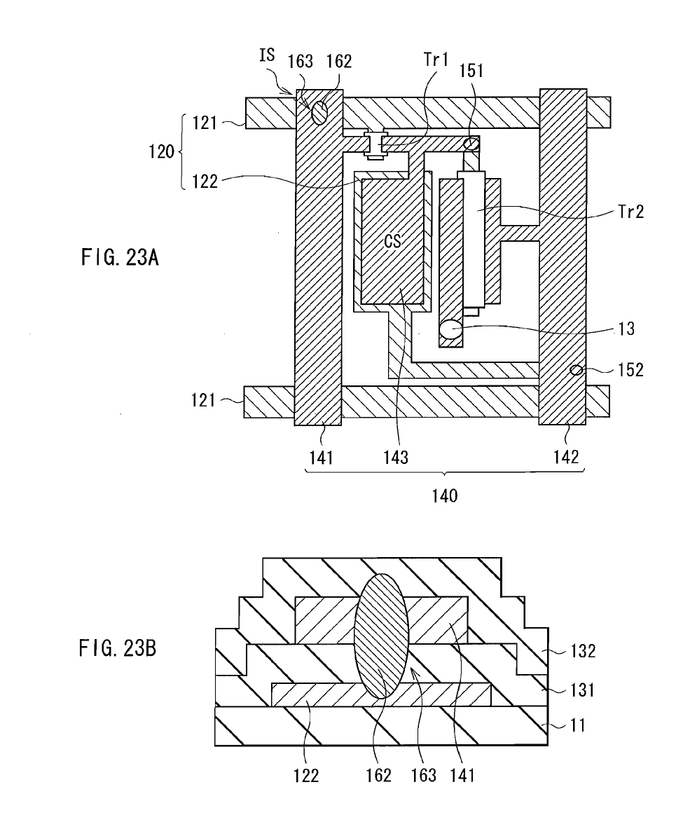

In the step, interlayer short 163, where the scan line 121 is shorted with the signal line 141 via the foreign substance 162, may occur in the intersection IS as shown in FIGS. 23A and 23B. Therefore, presence of the interlayer short 163 is checked by, for example, an electrical test, and then a position or size of the interlayer short is extracted by an optical test.

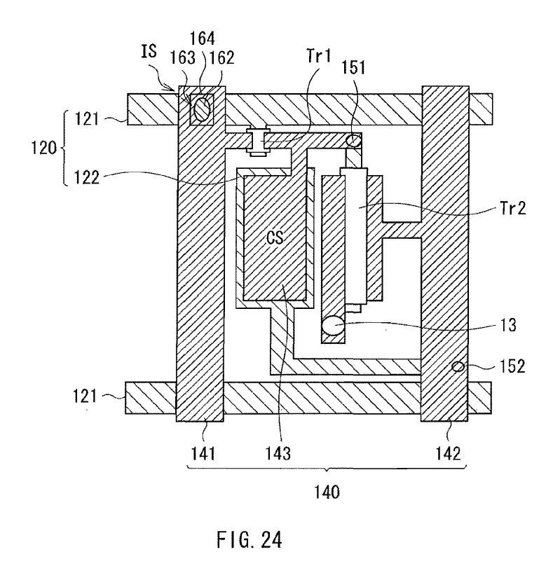

Next, laser light LB is irradiated to a short-included region 164 by the repair device shown in FIGS. 8 and 9 to repair the interlayer short 163 as shown in FIG. 24.

Step of Forming Organic Light Emitting Elements 10R, 10G and 10B on Wiring Board 1

The interlayer short 163 in the wiring board 1 is repaired. Then, organic light emitting elements 10R, 10G and 10B are formed according to the steps shown in FIGS. 12A to 14B, so that a display device may be formed as in the first embodiment.

Operation of the display device is the same as in the first embodiment.

In this way, according to the method of manufacturing the display device of the embodiment, laser light LB having a pulse width of 10 picoseconds or less is irradiated to the short-included region 164 including the interlayer short 163 in order to remove at least the signal line 141 between the scan line 121, the insulating film 131 and the signal line 141 within the short-included region 164 in a step of repairing the interlayer short 163, therefore the interlayer short formed in the intersection IS in the wiring board 1 may be repaired.

Particularly, since the scan line 121, the insulating film 131 and the signal line 141 within the short-included region 164 are removed, the interlayer short may be stably and securely repaired.

According to the display device of the embodiment, since the intersection IS in the wiring board 1 has the opening 161 where at least the signal line 141 is removed between the scan line 121, the insulating film 131 and the signal line 141, defective display caused by the interlayer short 163 in the intersection IS may be suppressed.

The embodiment may be applied to an intersection IS between a scan line 121 and a source potential supply line 142.

### Fourth Embodiment

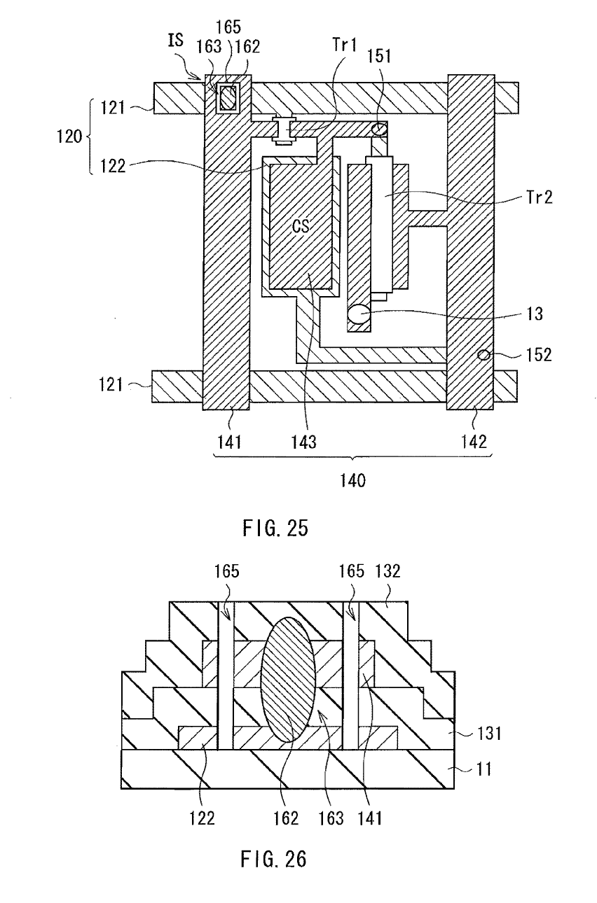

FIG. 25 shows an example of a planar configuration of a pixel drive circuit 111 of a display device according to a fourth embodiment of the invention. The display device has the same configuration as in the second embodiment except that a groove 165 is provided in an intersection IS between a scan line 121 and a signal line 141. Therefore, corresponding components are described with the same reference numerals or signs.

FIG. 26 shows an example of a sectional configuration of the intersection IS. In the intersection IS, interlayer short 163 is directly left, and the groove 165 encloses the interlayer short 163. In the groove 165, the signal line 141, an insulating film 131 and the scan line 121 are removed. Thus, in the display device, defective display caused by the interlayer short in the intersection IS may be suppressed as in the third embodiment.

The groove 165 is a groove left as a repair mark made in repairing interlayer short formed in the intersection IS during a manufacturing process, and therefore need not be necessarily formed in each of all intersections IS.

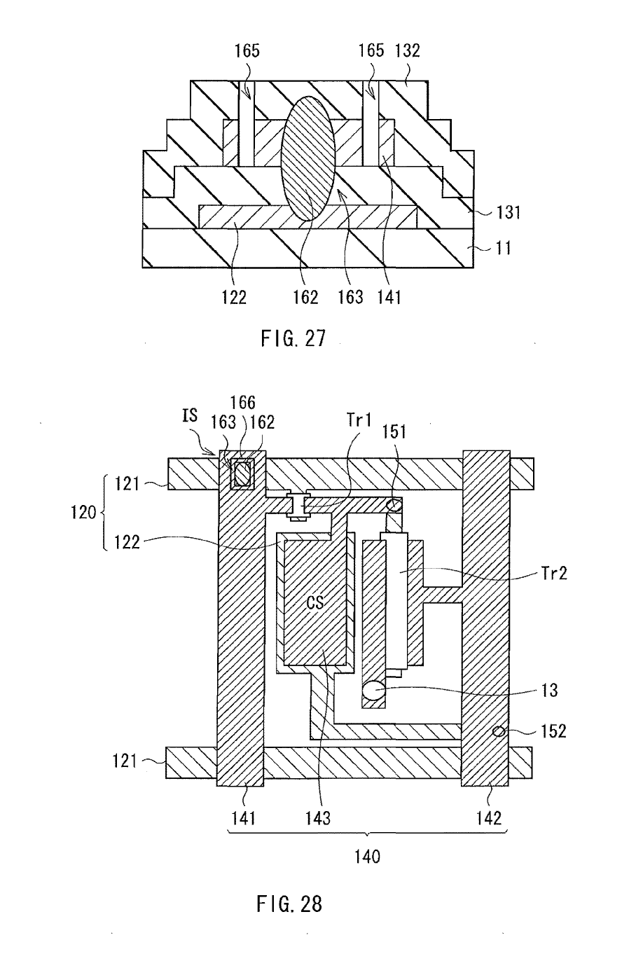

FIG. 27 shows another example of a sectional configuration of the intersection IS. In the groove 165, only the signal line 141 may be removed between the signal line 141, the insulating film 131 and the scan line 121 as in the opening 161. In this case, a conductive foreign substance 162 causing interlayer short may be left in the insulating film 131 and the scan line 121.

In the groove 165, the signal line 141, the insulating film 131 and the scan line 121 are preferably removed as shown in FIG. 26, rather than only the signal line 141 as shown in FIG. 27. This is because stable and secure repair is enabled thereby.

The groove 165 and the opening 161 may be combined in the same wiring board 1 or the same display device. In such a case, the groove 165 and the opening 161 are preferably properly used depending on size of the interlayer short 163 as described in the following manufacturing method.

The display device may be manufactured, for example, in the following way.

Step of Forming Wiring Board

First, a lower conductive film 120, the insulating film 131, and an upper conductive film 140 are formed on a substrate 11 according to the step shown in FIGS. 7A and 7B, so that a wiring board 1 is formed as in the first embodiment.

Step of Repairing Interlayer Short

Next, presence of the interlayer short 163 in the intersection IS as shown in FIGS. 23A and 23B is checked by, for example, an electrical test, and then a position or size of the interlayer short is extracted by an optical test according to the steps shown in FIG. 18 as in the second embodiment (step S101).

Then, the interlayer short 163 is repaired by using the repair device shown in FIGS. 8 and 9. At that time, a method of irradiating laser light LB is preferably varied depending on size of the interlayer short 163 as in the second embodiment. This is because the interlayer short 163 may be securely repaired thereby regardless of size of the interlayer short.

Specifically, a certain threshold value (for example, 20 μm square) is set for size of the interlayer short 163, and whether size of the interlayer short 163 is not larger than or larger than the threshold value is determined according to the steps shown in FIG. 18. When size of the interlayer short 163 is not larger than the threshold value (20 μm square or smaller), the laser light LB is preferably irradiated to a short-included region 164 (step S102). In this case, a repair method is the same as in the first or third embodiment.

In contrast, when size of the interlayer short 163 is larger than the threshold value (larger than 20 μm square), the laser light LB is preferably irradiated to a frame region 166 enclosing the interlayer short 163 (step S103). This is because when size of the interlayer short 163 is large, slit size for adjusting a beam shape of the laser light LB may not meet the size, or even if the slit size meets the size, laser energy distribution in an irradiation plane becomes irregular, leading to reduction in repair reliability. In this case, a repair method is the same as in the second embodiment.

Step of Forming Organic Light Emitting Elements 10R, 10G and 10B on Wiring Board 1

In this way, the interlayer short 163 in the wiring board 1 is repaired. Then, organic light emitting elements 10R, 10G and 10B are formed according to the steps shown in FIGS. 12A to 14B, so that a display device may be formed as in the first embodiment.

Operation of the display device is the same as in the first embodiment.

In this way, according to a method of manufacturing the display device of the embodiment, since a method of irradiating the laser light LB is varied depending on size of the interlayer short 163 in a step of repairing the interlayer short 163, the interlayer short 163 formed in the intersection IS in the wiring board 1 may be securely repaired regardless of size of the interlayer short.

Particularly, when size of the interlayer short 163 is not larger than the threshold value, the laser light LB is irradiated to the short-included region 164. Therefore, processing area may be minimized, and process time may be reduced since the laser light LB may be irradiated at rest.

When size of the interlayer short 163 is larger than the threshold value, the laser light LB is irradiated to a frame region 166 enclosing the interlayer short 163. Therefore, even if size of the interlayer short 163 is large, reduction in repair reliability may be suppressed.

Furthermore, since the scan line 121, the insulating film 131 and the signal line 141 within the frame region 166 are removed, the interlayer short may be stably and securely repaired.

According to the display device of the embodiment, since the intersection IS in the wiring board 1 has the groove 165 where at least the signal line 141 is removed between the scan line 121, the insulating film 131 and the signal line 141, defective display caused by the interlayer short 163 in the intersection IS may be suppressed.

The embodiment may be applied to an intersection IS between a scan line 121 and a source potential supply line 142.

### EXAMPLES

Furthermore, specific examples according to the invention are described.

### Example 1

The wiring board 1 was prepared in the same way as in the first embodiment. The resultant wiring board 1 was measured in size of the interlayer short 163 formed in the capacitor CS. As a result, the interlayer short had a diameter of 5 μm.

Laser light LB having a pulse width of 10 picoseconds or less was irradiated to the short-included region 164 including the interlayer short 163, namely, irradiated covering the interlayer short 163. At that time, the laser light LB was adjusted to be 400 nm in wavelength, 500 Hz in repetition, 3 picoseconds in pulse width, and 10 μm square in irradiation beam shape, and outputted by 4000 pulses at rest for irradiation for about 8 seconds while energy density was set to 0.2 J/cm² on a surface of the wiring board 1. The laser light LB was shaped by an aperture (not shown), and irradiated while being observed using the objective lens 811 of the optical system 810 with 50 magnifications and an operation distance of 15 mm.

Thus, the lower electrode 122, the insulating film 131, and the upper electrode 143 within the short-included region 164 were removed, so that the interlayer short 163 was repaired, and the opening 161 was formed.

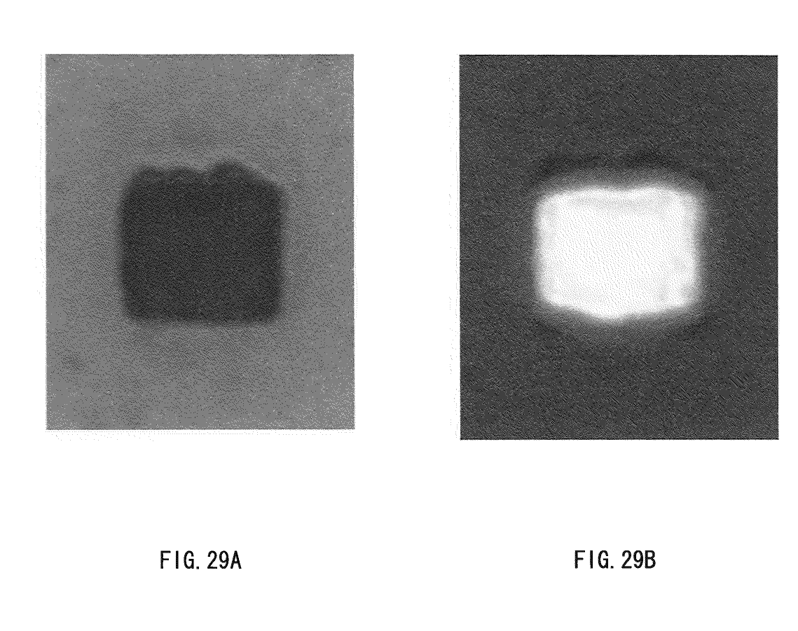

FIGS. 29A and 29B show a reflection photograph and a transmission photograph of the opening 161 respectively. As known from FIG. 29B, light was transmitted through the opening 161, from which the lower electrode 122 was confirmed to be removed.

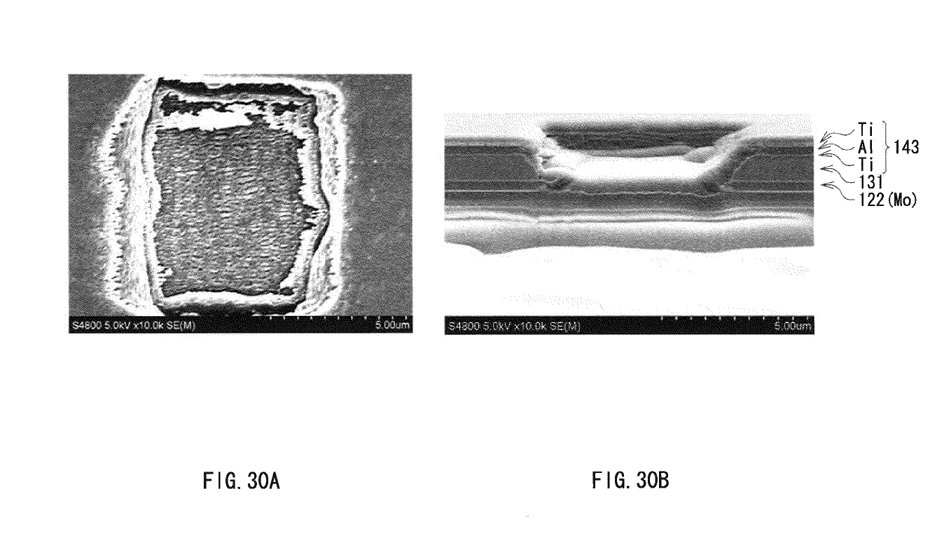

FIGS. 30A and 30B show SEM (Scanning Electron Microscope) photographs of a top and a section of the opening 161 respectively. As known from FIG. 30B, the Ti layer, Al layer and Ti layer of the upper electrode 143, the insulating film 131, and the Mo layer of the lower electrode 122 were confirmed to be removed.

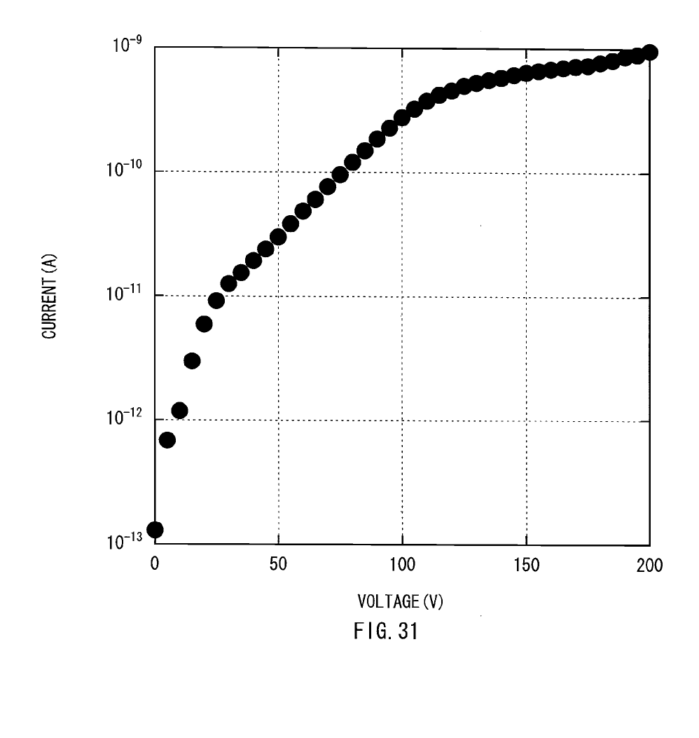

When a voltage of 0 V to 200 V was applied between the lower electrode 122 and the upper electrode 143 of the repaired capacitor CS, a leak current value was investigated. FIG. 31 shows a result of the investigation. As known from FIG. 31, even if the applied voltage was increased to 200 V, dielectric breakdown did not occur, and thus reliable repair was confirmed.

### Comparative Example 1

As comparative Example 1, interlayer short was tried to be repaired in the same way as in the example 1 except that laser light having a pulse width of larger than 10 picoseconds was used. At that time, laser light LB was adjusted to be 532 nm in wavelength, 10 Hz in repetition, 10 nanoseconds in pulse width, and 8 μm square in irradiation beam shape, and outputted by 5 pulses at rest for irradiation while energy density is set to 2.0 J/cm² on a surface of a wiring board.

A capacitor of the comparative example 1 after the repair try was also investigated in leak current value as in the example 1. As a result, the leak current value was 10 mA being a current value of an upper measurement limit. That is, the capacitor was still shorted, and the interlayer short was not able to be repaired.

That is, it was known that when laser light LB having a pulse width of 10 picoseconds or less was irradiated to the short-included region 164 including the interlayer short 163, the interlayer short 163 formed in the capacitor CS in the wiring board 1 was able to be repaired.

### Example 2

The interlayer short 163 was repaired in the same way as in the example 1 except that at least the upper electrode 143 was removed between the lower electrode 122, the insulating film 131, and the upper electrode 143 within the short-included region 164. At that time, the laser light LB was adjusted to be 400 nm in wavelength, 500 Hz in repetition, 3 picoseconds in pulse width, and 10 μm square in irradiation beam shape, and outputted by 4000 pulses at rest for irradiation for about 8 seconds while energy density was set to 0.03 J/cm² on a surface of the wiring board 1.

The repaired capacitor of the example 2 was also investigated in leak current value as in the example 1. As a result, dielectric breakdown occurred at an applied voltage of 150 V to 200 V.

Particularly, the lower electrode 122, the insulating film 131, and the upper electrode 143 within the short-included region 164 were removed, the interlayer short was able to be stably and securely repaired.

That is, it was known that when the lower electrode 122, the insulating film 131, and the upper electrode 143 within the short-included region 164 were removed, the interlayer short was able to be stably and securely repaired.

Module and Application Examples

Hereinafter, application examples of the display device described in each of the embodiments are described. The display device of each embodiment may be used for an electronic device in any field where an externally inputted video signal or an internally generated video signal is displayed in a form of an image or a picture, the electronic device including a television apparatus, a digital camera, a notebook computer, a mobile terminal such as mobile phone, or a video camera.

Module

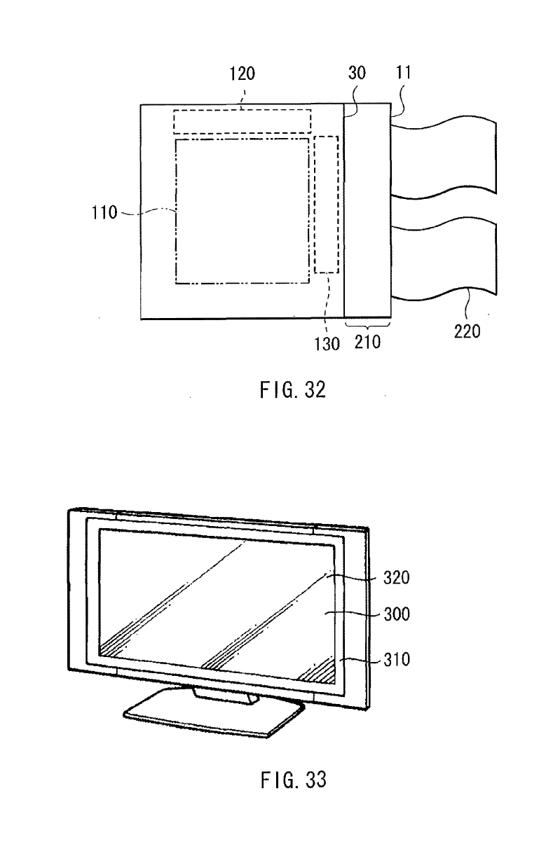

The display device of each of the embodiments is incorporated into various electronic instruments including application examples 1 to 5 described later, for example, as a module as shown in FIG. 32. In the module, for example, a region 210 exposed from a seal substrate 30 and an adhesion layer 20 is provided on one side of a transfer target substrate 11, and external connection terminals (not shown) are formed on the exposed region 210 by extending lines of a signal line drive circuit 120 and lines of a scan line drive circuit 130. The external connection terminals may be provided with a flexible printed circuit (FPC) for inputting/outputting signals.

### Application Example 1

FIG. 33 shows appearance of a television apparatus applied with the display device of each embodiment. The television apparatus has, for example, a picture display screen 300 including a front panel 310 and a filter glass 320, and the picture display screen 300 includes the display device according to each embodiment.

### Application Example 2

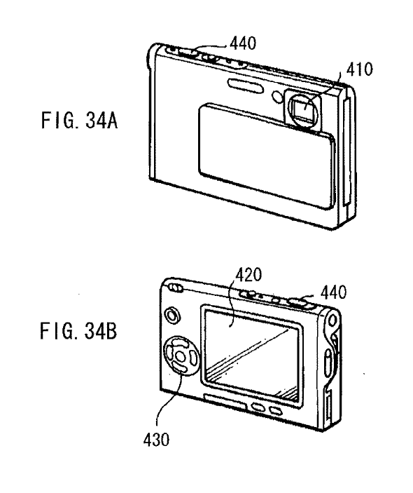

FIGS. 34A and 34B show appearance of a digital camera applied with the display device of each embodiment. The digital camera has, for example, a flash light emitting section 410, a display section 420, a menu switch 430, and a shutter button 440, and the display section 420 includes the display device according to each embodiment.

### Application Example 3

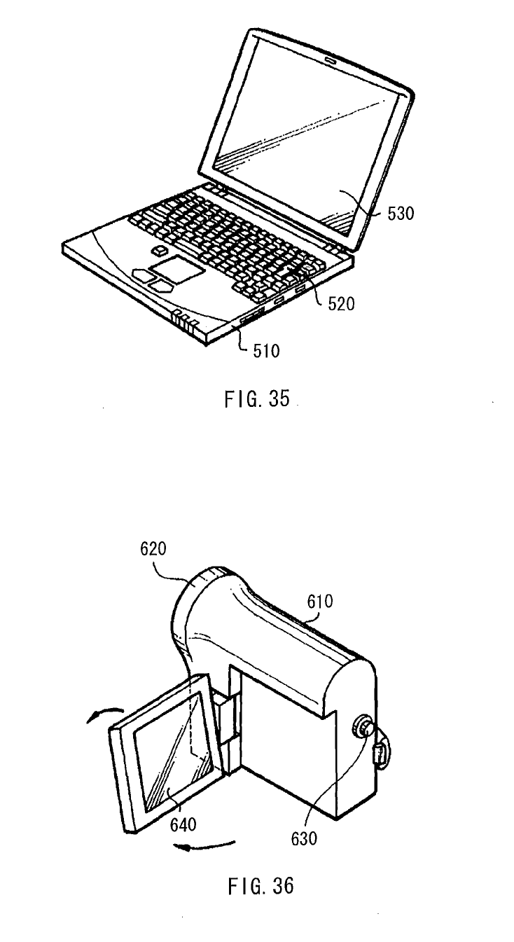

FIG. 35 shows appearance of a notebook computer applied with the display device of each embodiment. The notebook computer has, for example, a body 510, a keyboard 520 for input operation of letters and the like, and a display section 530 displaying images, and the display section 530 includes the display device according to each embodiment.

### Application Example 4

FIG. 36 shows appearance of a video camera applied with the display device of each embodiment. The video camera has, for example, a body 610, a lens 620 for photographing an object, the lens being provided on a front side face of the body 610, a photographing start/stop switch 630, and a display section 640, and the display section 640 includes the display device according to each embodiment.

### Application Example 5

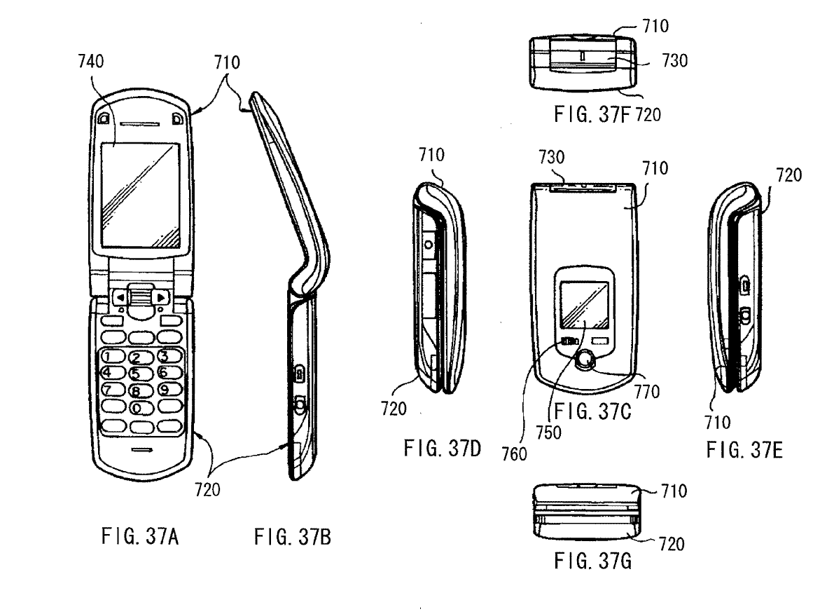

FIGS. 37A to 37G show appearance of a mobile phone applied with the display device of each embodiment. The mobile phone includes, for example, an upper housing 710 and a lower housing 720 connected to each other by a hinge 730, and has a display 740, a sub display 750, a picture light 760, and a camera 770. The display 740 or the sub display 750 includes the display device according to each embodiment.

While the invention has been described with embodiments hereinbefore, the invention is not limited to the embodiments, and various modifications and alterations may occur. For example, while the source potential supply lines 142 are formed in the upper conductive film 140 in the embodiments, the lines may be formed in the lower conductive film 120.

Moreover, for example, while the embodiments have been described with a case where a method of manufacturing the display device according to the embodiment of the invention is applied to the organic light emitting display device using the organic light emitting elements 10R, 10G and 10B, the invention may be widely applied to other flat display devices such as a liquid crystal display device.

Moreover, for example, while the embodiments have been described with a specific configuration of the repair device 800, the configuration of the repair device 800 is not limited to that. For example, while the embodiments have been described with a case where the wiring board 1 is moved by the movement mechanism 820 with respect to the optical system 810, the optical system 810 may be moved with respect to the wiring board 1, or both may be moved with respect to each other.

In addition, for example, while the embodiments have been described with a case where the local repair section 831 is flown by using the compressed gas G1, a flying method is not limited to such a static-pressure flying method using the compressed gas G1. The local repair section 831 may be fixed to a support or the like.

The present application contains subject matter related to that disclosed in Japanese Priority Patent Application JP 2009-028330 filed in the Japan Patent Office on Feb. 10, 2009, the entire content of which is hereby incorporated by reference.

It should be understood by those skilled in the art that various modifications, combinations, sub-combinations and alterations may occur depending on design requirements and other factors insofar as they are within the scope of the appended claims or the equivalent thereof.

What is claimed is:

1. A method of manufacturing a display device comprising steps of:
forming a wiring board having a lower conductive film, an insulating film and an upper conductive film in order on a substrate;
repairing interlayer short being short between the upper conductive film and the lower conductive film; and
forming display elements on the wiring board;
wherein laser light having a pulse width of 10 picoseconds or less is irradiated to a short-included region including the interlayer short in the step of repairing the interlayer short in order to remove at least the upper conductive film between the lower conductive film, the insulating film and the upper conductive film within the short-included region.

2. The method of manufacturing a display device according to claim 1,
wherein the upper conductive film, the insulating film and the lower conductive film within the short-included region are removed in the step of repairing the interlayer short.

3. The method of manufacturing a display device according to claim 1,
wherein a method of irradiating the laser light is varied depending on size of the interlayer short in the step of repairing the interlayer short.

4. The method of manufacturing a display device according to claim 3,
wherein whether the size of the interlayer short is not larger than or larger than a threshold value is determined, and when the size of the interlayer short is not larger than the threshold value, the laser light is irradiated to the short-included region, and when the size of the interlayer short is larger than the threshold value, the laser light is irradiated to a frame region enclosing the interlayer short in the step of repairing the interlayer short.

5. The method of manufacturing a display device according to claim 1,
wherein the wiring board has pixel drive circuits, each pixel drive circuit having transistors including the lower conductive film, the insulating film and the upper conductive film each, a capacitor including the lower conductive film, the insulating film and the upper conductive film, and the display elements, and
interlayer short in the capacitor is repaired in the step of repairing the interlayer short.

6. The method of manufacturing a display device according to claim 1,
wherein the wiring board has scan lines including one of the lower conductive film and the upper conductive film, and signal lines including the other of the lower conductive film and the upper conductive film, and
interlayer short in an intersection between one of the scan lines and one of the signal lines is repaired in the step of repairing the interlayer short.

7. The method of manufacturing a display device according to claim 6,
wherein the display elements are organic light emitting elements,
the wiring board has source potential supply lines including the lower conductive film or the upper conductive film, and
interlayer short in an intersection between one of the source potential supply lines and one of the scan lines or one of the signal lines is repaired in the step of repairing the interlayer short.

8. The method of manufacturing a display device according to claim 1,
wherein energy density per pulse of the laser light is 0.03 J/cm² to 0.5 J/cm².

9. The method of manufacturing a display device according to claim 1,
wherein the laser light is irradiated while being rested.

10. The method of manufacturing a display device according to claim 1,
wherein the laser light is irradiated while being scanned.

11. A display device comprising:
a wiring board having a lower conductive film, an insulating film and an upper conductive film in order on a substrate; and
display elements formed on the wiring board;
wherein the wiring board includes pixel drive circuits, each pixel drive circuit having transistors including the lower conductive film, the insulating film and the upper conductive film each, and a capacitor including the lower conductive film, the insulating film and the upper conductive film, and the display elements, and
the capacitor has an opening with at least the upper conductive film being removed between the lower conductive film, the insulating film and the upper conductive film.

12. The display device according to claim 11,
wherein the wiring board has scan lines including one of the lower conductive film and the upper conductive film, and signal lines including the other of the lower conductive film and the upper conductive film, and
an intersection between one of the scan lines and one of the signal lines has an opening with at least the upper conductive film being removed between the lower conductive film, the insulating film and the upper conductive film.

13. The display device according to claim 12,
wherein the display elements are organic light emitting elements,
the wiring board has source potential supply lines including the lower conductive film or the upper conductive film, and
an intersection between one of the source potential supply lines and one of the scan lines or one of the signal lines has an opening with at least the upper conductive film being removed between the lower conductive film, the insulating film and the upper conductive film.

14. The display device according to claim 11,
wherein the capacitor includes
interlayer short being short between the upper conductive film and the lower conductive film, and
a groove enclosing the interlayer short with at least the upper conductive film being removed between the lower conductive film, the insulating film and the upper conductive film.
